(19) United States
(12) Patent Application Publication
(10) Pub. No.: US 2019/0313533 A1
(43) Pub. Date: Oct. 10, 2019

(54) SELF-ORIENTATION AND SELF-PLACEMENT OF COMPUTING DEVICES IN A FLUID

(71) Applicant: INTERNATIONAL BUSINESS MACHINES CORPORATION, Armonk, NY (US)

(72) Inventors: Spyridon Skordas, Troy, NY (US); Lawrence A. Clevenger, Saratoga Springs, NY (US); Leigh Anne H. Clevenger, Rhinebeck, NY (US); Benjamin D. Briggs, Waterford, NY (US); Michael Rizzolo, Albany, NY (US); Maryam Ashoori, Scarsdale, NY (US); Arvind Kumar, Chappaqua, NY (US)

(21) Appl. No.: 15/949,741

(22) Filed: Apr. 10, 2018

(51) Int. Cl. H05K 3/28; H01L 25/00; H01L 33/52; H01L 25/16; H01L 21/56; H05K 3/30

(52) U.S. Cl. CPC H05K 3/284; H01L 25/50; H01L 33/52; H01L 25/167; H05K 2203/0776; H05K 3/303; H01L 2933/005; H05K 2203/166; H01L 21/56

(57) ABSTRACT

Methods for orientation and placement of computing devices are presented. Aspects include applying, using a viscous material application device, a layer of a viscous material to a surface of an object, the layer of the viscous material having a plurality of computing devices disposed therein. The layer of the viscous material is allowed to dry during a drying period, wherein each of the plurality of computing devices comprises a first material applied to a first side of each of the plurality of computing devices, the first material having a first characteristic. And each of the plurality of computing devices comprises a second material applied to a second side of each of the plurality of computing devices, the second material having a second characteristic. And each of the plurality of computing devices is configured to perform, during the drying period, a self-orientation operation.

### BACKGROUND

The present invention generally relates to small computing devices, and more specifically, to self-orientation and self-placement of small computing devices in a fluid.

With the continued reduction in the size of processors and computing devices, in general, new applications continue to arise in the field. Particularly, these small computing devices can be utilized in a mesh network. Mesh networks of small computing devices can include light emitting diodes (LEDs) which are applied to surfaces such as street signs. The mesh network can be applied to a surface using a viscous solution, such as paint. For example, patterns of the LEDs can be applied to a sign and can communicate with an emergency vehicle to indicate that other vehicles on the road should stop due to the emergency vehicle approaching. The mesh network of devices can utilize the LEDs to communicate messages and the like to other vehicles on the road. Also, based on traffic conditions, the mesh networks can alter the messages displayed on a sign. For example, speed can be controlled depending on a type of vehicle approaching the sign. For example, a yield sign can allow a passenger vehicle through an intersection faster than a larger, commercial vehicle.

### SUMMARY

Embodiments of the present invention are directed to a method for orientation and placement of computing devices. A non-limiting example of the method includes applying, using a viscous material application device, a layer of a viscous material to a surface of an object, the layer of the viscous material having a plurality of computing devices disposed therein. The layer of the viscous material is allowed to dry during a drying period, wherein each of the plurality of computing devices includes a first material applied to a first side of each of the plurality of computing devices, the first material having a first characteristic. And each of the plurality of computing devices includes a second material applied to a second side of each of the plurality of computing devices, the second material having a second characteristic. And each of the plurality of computing devices is configured to perform, during the drying period, a self-orientation operation.

Embodiments of the present invention are directed to a method for orientation and placement of computing devices. A non-limiting example of the method includes depositing a layer of a first material to a surface of an object, the first material having a first characteristic. Using a viscous material application device, a layer of a viscous material is applied to the surface of the object, the layer of the viscous material having a plurality of computing devices disposed therein. The layer of the viscous material is allowed to dry during a drying period, wherein each of the plurality of computing devices includes a second material applied to a first side of each of the plurality of computing devices, the second material having a second characteristic. And each of the plurality of computing devices includes a third material applied to a second side of each of the plurality of computing devices, the third material having a third characteristic. And each of the plurality of computing devices is configured to perform, during the drying period, a self-orientation operation.

Embodiments of the present invention are directed to a method for orientation and placement of computing devices. A non-limiting example of the method includes depositing a layer of magnetic material on a surface of an object. A layer of a first material is deposited on to the surface of the object, the first material having a first characteristic. Using a viscous material application device, a layer of the viscous material is applied to the surface of the object, the layer of the viscous material having a plurality of computing devices disposed therein. The layer of the viscous material is allowed to dry during a drying period, wherein each of the plurality of computing devices includes a second material applied to a first side of each of the plurality of computing devices, the second material having a second characteristic. And each of the plurality of computing devices includes a third material applied to a second side of each of the plurality of computing devices, the third material having a third characteristic. And each of the plurality of computing devices is configured to perform, during the drying period, a self-orientation operation.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a block diagram of a computer system for use in implementing one or more embodiments of the present invention;

FIG. 2 depicts a small computing device according to one or more embodiments of the invention;

FIG. 3 depicts structures during the application of a viscous material to a surface of an object, wherein the viscous material application process incorporates various automated computing device orientation operations according to one or more embodiments of the invention;

FIG. 4 depicts structures during the application of a viscous material to a surface of an object, wherein the viscous material application process incorporates various automated computing device orientation operations according to one or more embodiments of the invention;

FIG. 5 depicts structures during the application of a viscous material to a surface of an object, wherein the viscous material application process incorporates various automated computing device orientation operations according to one or more embodiments of the invention; and

FIG. 6 depicts structures during a method for fabricating chips with desired surface properties according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, miniaturization fabrication techniques allow for the production of computing devices on the order of millimeters in size, for example, 0.1×0.1 mm\hat{ }2. These small computing devices can be utilized in a mesh network. Particularly, the small computing devices can be arranged on a surface and components of the small computing devices, such as an LED, can be utilized to form light patterns on the surface. A potential application for this mesh of computing devices is their usage on the surface of a traffic sign. The mesh of computing devices can be applied to the surface of a traffic sign using a viscous medium, such as paint, which holds the computing devices in place. However, based on the miniaturization of the computing devices and their application to a surface to form a mesh network, powering the individual devices can be challenging. Also, as the devices would be applied to locations on walls, signs, and the like that would not have access to an external power source, a renewable power source would appropriate. One possible solution is to use solar cells added to the computing devices as a power supply. One drawback to the usage of solar cells is the need to control the orientation of the computing device (e.g., the solar cell must face towards light). When applying the mesh network of computing devices to a surface using paint, the orientation is random. With a random orientation, the system might not have enough power to operate, or might not operate efficiently. Also, orientation of these small computing devices with manual placement can be very time-consuming, expensive, and prone to error.

Turning now to an overview of the aspects of the invention, one or more embodiments of the invention address the above-described shortcomings of the prior art by providing a method and structure for automatically achieving predetermined orientation and placement of small computing devices. As mentioned above, small computing devices can be applied to a large surface such as a wall, a sign, and the like utilizing a viscous medium (e.g., paint). The viscous medium can be mixed with the small computing devices and applied to a large surface of an object (such as a wall or sign) where the small computing devices are held in place by the viscous medium. When applied to the large surface through the viscous medium, embodiments of the invention achieve an orientation of the small computing devices that is appropriate for various applications and for efficient usage of a power supply. In embodiments of the invention, the small computing devices include on one side a solar cell, which serves as the power supply. In embodiments of the invention, the small computing devices are positioned such that their solar cells are facing in a direction of a light source, thereby ensuring that the computing devices will operate properly. In embodiments of the invention, the small computing devices are also oriented such that additional components (e.g., a light emitting diodes (LED)) are facing in a predetermined direction.

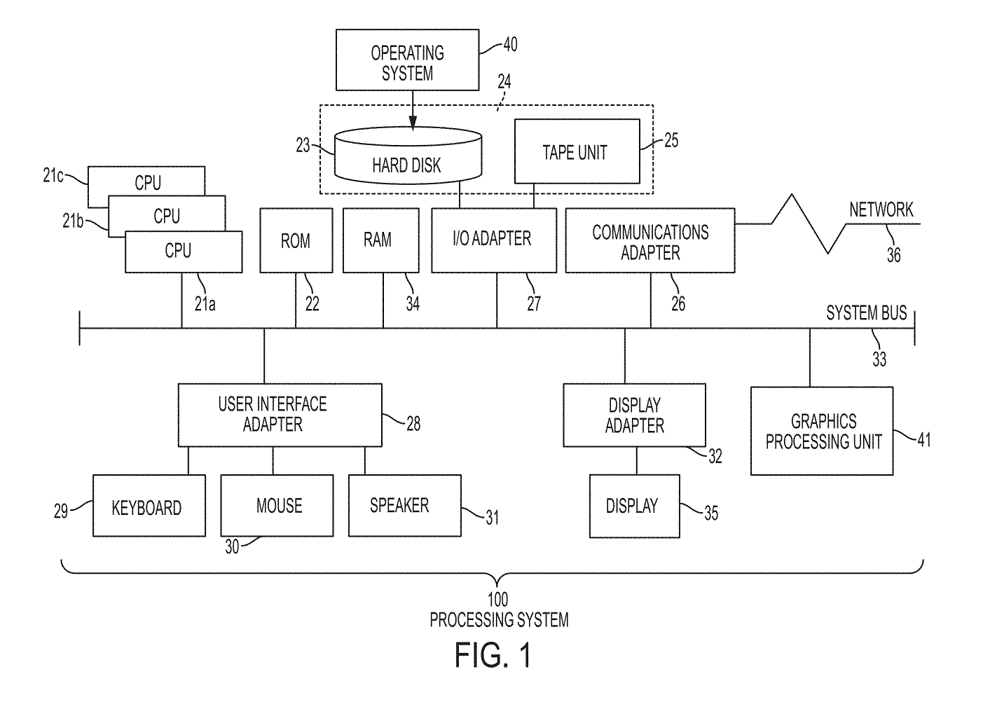

Referring to FIG. 1, there is shown an embodiment of a processing system 100 for implementing the teachings herein. In this embodiment of the invention, the system 100 has one or more central processing units (processors) 21a, 21b, 21c, etc. (collectively or generically referred to as processor(s) 21). In one or more embodiments of the invention, each processor 21 can include a reduced instruction set computer (RISC) microprocessor. Processors 21 are coupled to system memory 34 and various other components via a system bus 33. Read only memory (ROM) 22 is coupled to the system bus 33 and can include a basic input/output system (BIOS), which controls certain basic functions of system 100.

FIG. 1 further depicts an input/output (I/O) adapter 27 and a network adapter 26 coupled to the system bus 33. I/O adapter 27 can be a small computer system interface (SCSI) adapter that communicates with a hard disk 23 and/or tape storage drive 25 or any other similar component. I/O adapter 27, hard disk 23, and tape storage device 25 are collectively referred to herein as mass storage 24. Operating system 40 for execution on the processing system 100 can be stored in mass storage 24. A network adapter 26 interconnects bus 33 with an outside network 36 enabling data processing system 100 to communicate with other such systems. A screen (e.g., a display monitor) 35 is connected to system bus 33 by display adaptor 32, which can include a graphics adapter to improve the performance of graphics intensive applications and a video controller. In one embodiment of the invention, adapters 27, 26, and 32 can be connected to one or more I/O busses that are connected to system bus 33 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 33 via user interface adapter 28 and display adapter 32. A keyboard 29, mouse 30, and speaker 31 all interconnected to bus 33 via user interface adapter 28, which can include, for example, a Super I/O chip integrating multiple device adapters into a single integrated circuit.

In exemplary embodiments of the invention, the processing system 100 includes a graphics processing unit 41. Graphics processing unit 41 is a specialized electronic circuit designed to manipulate and alter memory to accelerate the creation of images in a frame buffer intended for output to a display. In general, graphics processing unit 41 is very efficient at manipulating computer graphics and image processing and has a highly parallel structure that makes it more effective than general-purpose CPUs for algorithms where processing of large blocks of data is done in parallel.

Thus, as configured in FIG. 1, the system 100 includes processing capability in the form of processors 21, storage capability including system memory 34 and mass storage 24, input means such as keyboard 29 and mouse 30, and output capability including speaker 31 and display 35. In one embodiment of the invention, a portion of system memory 34 and mass storage 24 collectively store an operating system coordinate the functions of the various components shown in FIG. 1.

The above-described aspects of the invention can be implemented by applying a hydrophobic or hydrophilic (depending on the viscous medium) layer on the small computing device. With the solar cell and LED on the opposite side of the hydrophobic or hydrophilic layer, the computing device rises to the surface and self-orients so that the solar cell and LED are facing up from the surface. In embodiments of the invention, a layer of ferromagnetic material can be applied to a side of the computing devices and a magnetic sheet can be placed under the surface to orient the computing devices in the viscous material before the viscous material dries. In embodiments of the invention, the surface to which the viscous material is being applied can be pre-coated with a patterned hydrophobic or hydrophilic layer prior to applying the viscous material having the small computing devices.

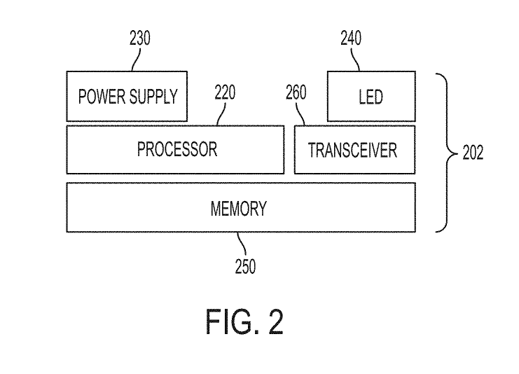

Turning now to a more detailed description of aspects of the present invention, FIG. 2 depicts a small computing device according to one or more embodiments of the invention. The computing device 202 includes a memory 250, a processor 220, a power supply 230, a light emitting diode (LED) 240, and a transceiver 260. In one or more embodiments of the invention, the power supply 230 is a solar cell (photovoltaic cell) or any electrical device that can convert the energy of light into electricity. In embodiments of the invention, the power supply 230 can be a radio frequency (RF) power supply. As shown in the illustrative example, the power supply 230 and LED 240 are arranged on one side of the computing device 202 in accordance with aspects of the invention.

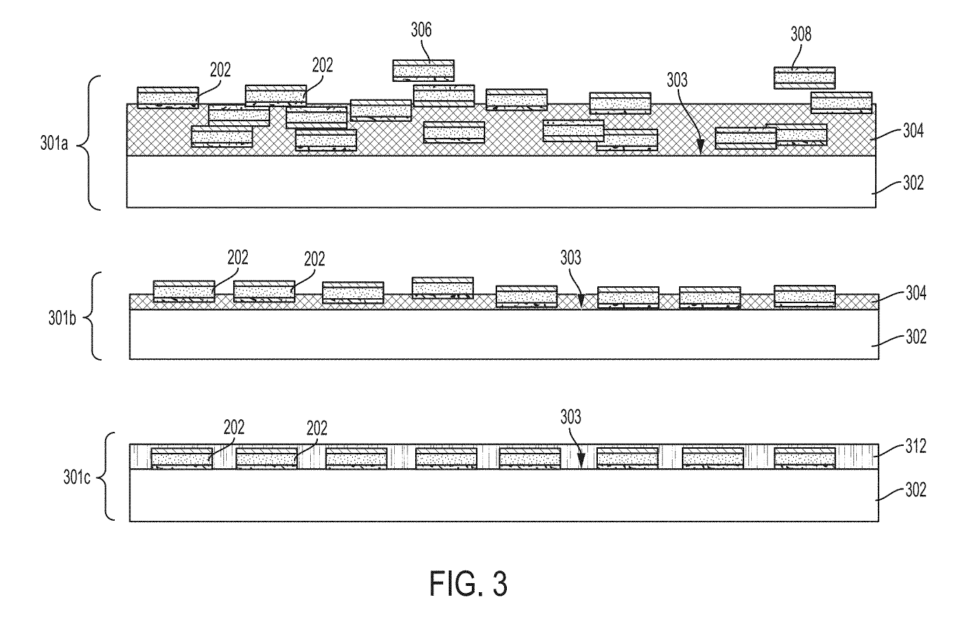

FIG. 3 depicts structures during the application of a viscous material to a surface of an object, wherein the viscous material application process incorporates various automated computing device orientation operations (301a, 301b, 301c) according to embodiments of the invention. The structures include an object 302, a viscous material 304, and computing devices 202, configured and arranged as shown. The object 302 includes a surface 303. The surface 303 of the object 302 can be any type of surface such as wood, metal, and the like. In one or more embodiments of the invention, multiple computing devices 202 can be mixed in with the viscous material 304. In embodiments of the invention, the viscous material can be paint. The paint can be a water based paint or an oil based paint. In embodiments of the invention, the small computing devices 202 have a first material 306 layer and a second material 308 layer applied to opposite sides of the computing devices 202.

The automated computing device orientation operations 301a, 301b, 301c depicted in FIG. 3 will now be described. At operation 301a (initial dispersion), the viscous material 304 is applied to the surface 303 of the object 302. The location and orientation of the computing devices 202 during the initial dispersion operation 301a can be random in that some computing devices 202 can overlap each other, and some computing devices 202 can be facing an unwanted direction (i.e., a direction other than the desired predetermined direction/orientation). In the illustrative example, the viscous material 204 is an aqueous solution, and the first material 306 is a hydrophobic material. Hydrophobicity is a physical property that results in the repelling of water. The second material 308 is a hydrophilic material. Hydrophilicity is a physical property that results in attraction of water.

At operation 301b, as the aqueous solution dries, the computing devices 202 will float with the first material 306 (hydrophobic) facing up (or away from the surface) and the second material 308 (hydrophilic) will continue to contact the aqueous solution 304. This is achieved by capillary forces promoting separation of the computing devices 202 with the hydrophilic promoting a downward orientation.

At operation 301c, the surface 303 of the object 302 has dried completely, and computing devices have automatically achieved the desired orientation in which the computing devices 202 face up so that the first material 306 layer is facing away from the surface 303 of the object 302. In one or more embodiments of the invention, operation 301b can include agitation of the object 302, which can assist with self-orientation of the computing devices 202. Examples of agitation include rotation of the object 302, blowing an air stream against the viscous material 304, or vibrating the object 302 utilizing a mechanical device for vibration. At operation 301c, a clear material or adhesive 312 can be applied to the computing devices 202 and the surface 303 of the object 302, as needed. In one or more embodiments, the viscous material can be applied by use of a liquid dispense nozzle and/or spraying equipment while the substrates are on a wafer-chuck in specific equipment or in-situ if the substrates are too big or fixed to be placed on a wafer-chuck. Any needed drying can be enhanced as needed by use of warm/hot air dryers. Agitation can be achieved, as needed, by rotating and/or vibrating chucks where the substrates are placed on, or by use of air flow in situ or by attaching vibration/pulsing generation equipment to surfaces.

In one or more embodiments of the invention, the viscous material 304 can be an oil based material. In this case, the hydrophobic and hydrophilic material layers will be reversed. The first material 306 will be hydrophilic and the second material 308 will be hydrophobic for oil based materials. In one or more embodiments of the invention, the first material 306 and second material 308 can be super-hydrophobic and super-hydrophilic coatings of the computing devices 202 depending on the viscous material 304. A superhydrophobic coating is a nanoscopic surface layer that repels water intensely, whereas a superhydrophilic coating is a nonascopic surface layer that attracts water intensely.

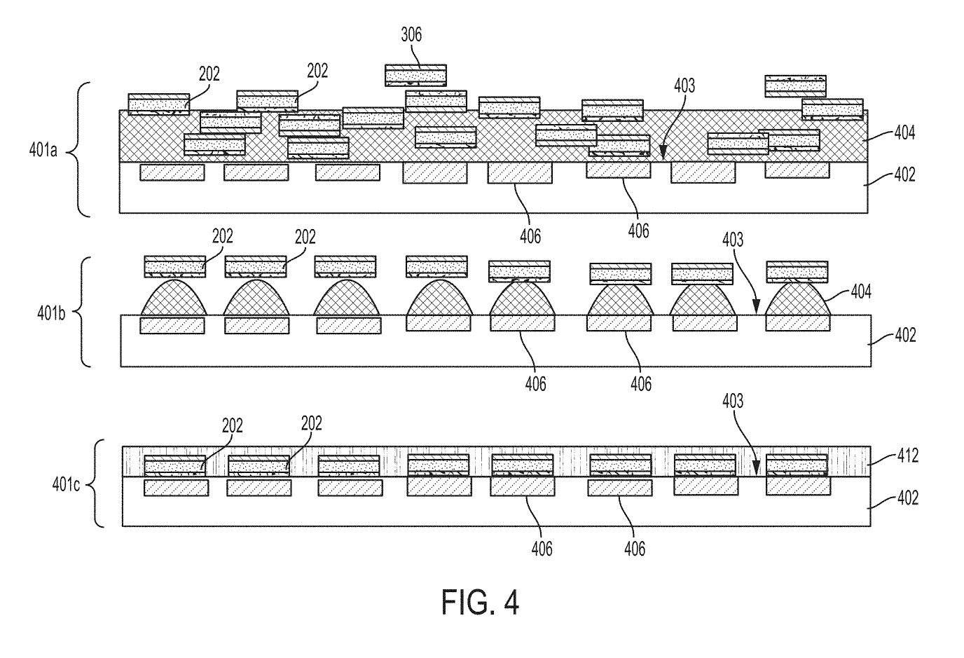

FIG. 4 depicts structures during the application of a viscous material to a surface of an object, wherein the viscous material application process incorporates various automated computing device orientation operations (401a, 401b, 401c) according to one or more embodiments of the invention. The structures include an object 402, a viscous material 404, and computing devices 202, configured and arranged as shown. The object 502 includes a surface 403. The surface 403 of the object 402 can be any type of surface such as wood, metal, and the like. In one or more embodiments of the invention, multiple computing devices 202 can be mixed in with the viscous material 404. In embodiments of the invention, the viscous material 404 can be paint. The paint can be water based paint or an oil based paint. The automated computing device orientation operations 401a, 401b, 401c depicted in FIG. 4 will now be described. At operation 401a (initial dispersion), a viscous material 404 can be dispersed onto the surface 403 of an object 402. The initial dispersion of the viscous material 404 can be done utilizing any means of viscous material application. The object 402 can be initially coated in certain areas with a hydrophilic/hydrophobic material 406 (based on the type of viscous material). In the illustrative example, the viscous material 404 is an aqueous solution and a hydrophilic material 406 is utilized for coating the object 402 surface in accordance with aspects of the invention. At operation 401b, as the aqueous solution 404 dries, liquid droplets form on the hydrophilic areas 406. The first layer 306 which is a hydrophobic layer will be repelled by the liquid droplets. The second layer 308, a hydrophilic layer, are attracted to the liquid droplets. The orientation of the computing devices 202 show the first layer 306 facing away from the object 402 surface. In one or more embodiments of the invention, the power supply 230 (not shown) and LED 240 (not shown) are arranged, through the orientation operations described herein, to be facing away from the surface of the object 402 to allow for collection of light and display of the LED 204 facing away from the surface. In one or more embodiments of the invention, when the viscous material 404 has dried, as shown at operation 401c, a clear material 412 or adhesive material can be applied to the computing devices 202 and the object 402 to keep the computing devices 202 in place after self-orientation. In one or more embodiments of the invention, the viscous material 404 can be an oil based solution and the first material 306 is hydrophilic, the second material 308 is hydrophobic, and the areas 406 coated on the object 402 are hydrophobic.

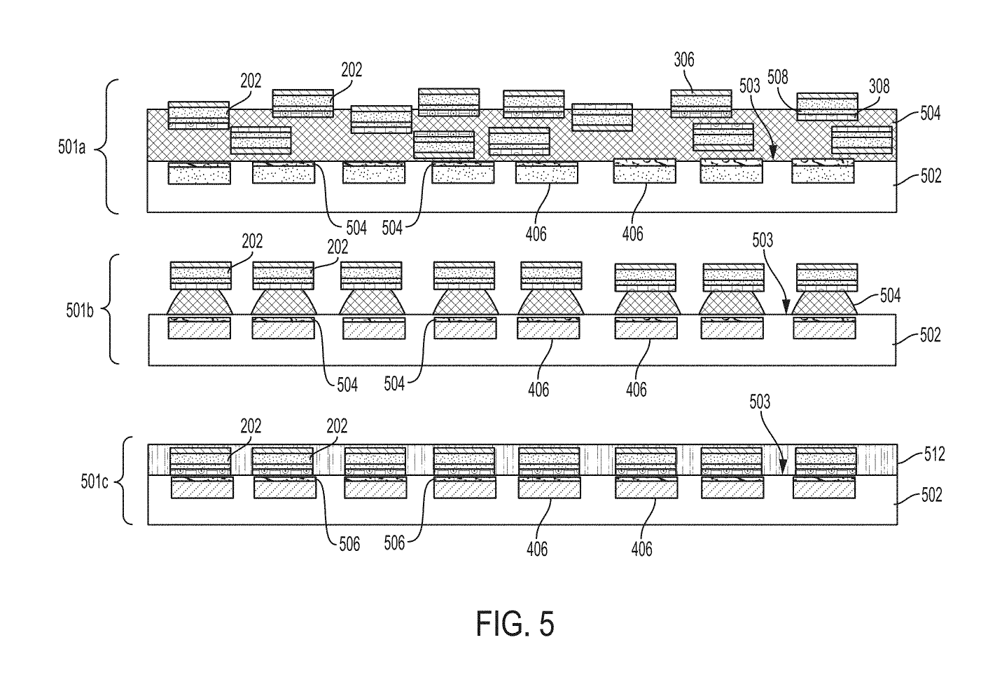

FIG. 5 depicts structures during the application of a viscous material to a surface of an object, wherein the viscous material application process incorporates various automated computing device orientation operations (501a, 501b, 501c) according to one or more embodiments of the invention. The structures include an object 502, a viscous material 504, and computing devices 202, configured and arranged as shown. The object 502 includes a surface 503. The surface 503 of the object 502 can be any type of surface such as wood, metal, and the like. In one or more embodiments of the invention, multiple computing devices 202 can be mixed in with the viscous material 504. In embodiments of the invention, the viscous material 504 can be paint. The paint can be a water based paint or an oil based paint. The automated computing device orientation operations 501a, 501b, 501c depicted in FIG. 5 will now be described. At operation 501a (initial dispersion), the viscous material 504 is applied to the surface 503 of the object 502. The surface 503 of the object 502 includes areas 406 coated with a hydrophobic or hydrophilic material and also a magnetic strip 504 in these areas 406. The computing devices 202 include a first material 306 coating, a second material coating 308, and a magnetic strip 508 within the computing device 202. As the viscous material dries, at operation 501b, liquid droplets form on the areas 406 with the hydrophobic/hydrophilic material coating. Also, the magnetic strips 504 in the object 502 further guide the orientation of the computing devices 202 by attracting the corresponding magnetic strips 508 in the computing devices 202. Operation 501b results in enhanced alignment and stronger bonding to the surface because the computing devices 202 are additionally guided to the magnetic areas 504 along with the hydrophilicity/hydrophobicity properties. At operation 501c, the viscous material 504 dries or evaporates and a clear material 512 or adhesive material can be applied to the computing devices 202 and the object 502. In one or more embodiments of the invention, the magnetic strip 508 can be a magnetic layer over the entire surface of the object 502.

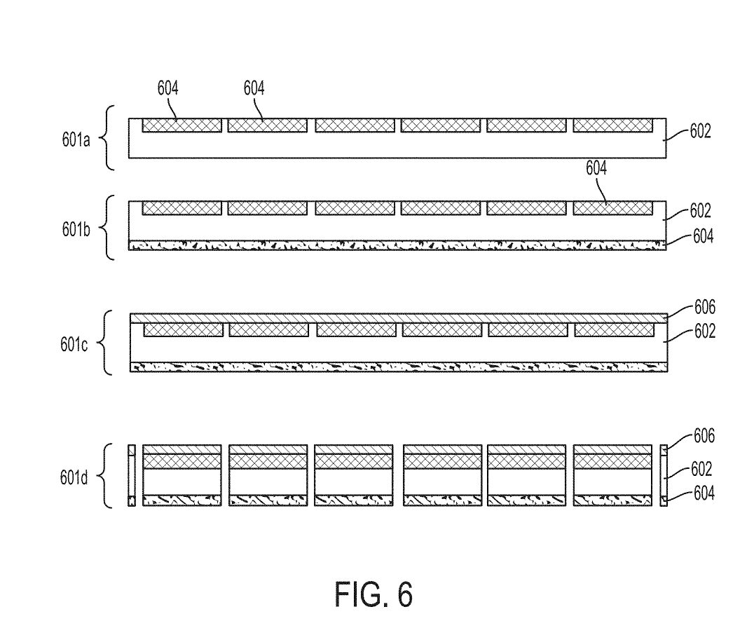

FIG. 6 depicts structures 602 after various fabrication operations (601a, 601b, 601c, 601d) of a method for fabricating chips with desired surface properties according to one or more embodiments of the invention. A finished wafer 602, which includes defined functional chips 604, is shown at operation 601a. At operation 601b, the backside of the wafer 602 is coated with a hydrophilic material 604. This can be performed using any commercial means. The front side of the wafer 602 is coated with a clear hydrophobic material 606, as shown at operation 601c. At operation 601d, a dicing process separates the chips with desired properties for later dispersing in an appropriate viscous material. In one or more embodiments of the invention, the hydrophilic material 604 coating and the hydrophobic material 606 coating are reversed based on the type of viscous medium utilized for dispersing.

An application can be the coating of a highway sign with the viscous material 404 having the small computing devices 202. Once the computing devices 202 self-orient, the processor 220 can be programmed to display the LED 240. The arrangement of the small computing device 202 can show patterns and the LEDs 240 for each computing device 202 can be displayed at different intervals for utilization with the highway sign.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user' s computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments of the invention, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for orientation and placement of computing devices, the method comprising:
applying, using a viscous material application device, a layer of a viscous material to a surface of an object, the layer of the viscous material having a plurality of computing devices disposed therein; and
allowing the layer of the viscous material to dry during a drying period;
wherein each of the plurality of computing devices comprises a first material applied to a first side of each of the plurality of computing devices, the first material having a first characteristic;
wherein each of the plurality of computing devices comprises a second material applied to a second side of each of the plurality of computing devices, the second material having a second characteristic;
wherein each of the plurality of computing devices is configured to perform, during the drying period, a self-orientation operation.

2. The method of claim 1, wherein the self-orientation operations are based at least in part on the first characteristic and the second characteristic in the viscous material.

3. The method of claim 1 further comprising agitating, using a vibration tool, the surface of the object.

4. The method of claim 3, wherein the self-orientation operations are based at least in part on the first characteristic, the second characteristic, and the agitation of the surface of the object.

5. The method of claim 2, wherein the viscous material comprises a water-based material.

6. The method of claim 5, wherein:
the first characteristic comprises a hydrophilicity; and
the second characteristic comprises a hydrophobicity.

7. The method of claim 6, wherein each of the plurality of computing devices in the viscous material comprises:
the first side of each of the plurality of computing devices facing away from the surface of the object based on the first characteristic; and
the second side of each of the plurality of computing devices faces towards the surface of the object based on the second characteristic.

8. The method of claim 1, wherein each of the plurality of computing devices includes a power supply disposed on the first side.

9. The method of claim 2, wherein the viscous material comprises an oil-based material.

10. The method of claim 9, wherein:
the first characteristic comprises a hydrophilicity; and
the second characteristic comprises a hydrophobicity.

11. The method of claim 10, wherein:
based at least in part on the first characteristic and the second characteristic, each of the plurality of computing devices perform the self-orientation operations;
the first side of each of the subset of the plurality of computing devices faces toward the surface of the object; and
the second side of each of the subset of the plurality of computing devices faces away from the surface of the object.

12. A method for orientation and placement of computing devices, the method comprising:
depositing a layer of a first material to a surface of an object, the first material having a first characteristic;
applying, using a viscous material application device, a layer of a viscous material to the surface of the object, the layer of the viscous material having a plurality of computing devices disposed therein; and
allowing the layer of the viscous material to dry during a drying period;
wherein each of the plurality of computing devices comprises a second material applied to a first side of each of the plurality of computing devices, the second material having a second characteristic;
wherein each of the plurality of computing devices comprises a third material applied to a second side of each of the plurality of computing devices, the third material having a third characteristic;
wherein each of the plurality of computing devices is configured to perform, during the drying period, a self-orientation operation.

13. The method of claim 12, wherein the layer of the first material is a patterned layer applied to a plurality of areas of the surface of the object.

14. The method of claim 12, wherein the self-orientation operations are based at least in part on the first characteristic, the second characteristic, and the third characteristic in the viscous material.

15. The method of claim 14, wherein the viscous material comprises a water-based material;
wherein the first characteristic and the third characteristic comprise hydrophilicity; and
wherein the second characteristic comprises hydrophobicity.

16. The method of claim 15, wherein each of the plurality of computing devices in the viscous material comprises:
the first side of each of the plurality of computing devices facing away from the surface of the object based on the second characteristic; and
the second side of each of the plurality of computing devices faces towards the surface of the object based on the first characteristic and the third characteristic.

17. A method for orientation and placement of computing devices, the method comprising:
depositing a layer of magnetic material on a surface of an object;
depositing a layer of a first material on the surface of the object, the first material having a first characteristic;
applying, using a viscous material application device, a layer of the viscous material to the surface of the object, the layer of the viscous material having a plurality of computing devices disposed therein; and
allowing the layer of the viscous material to dry during a drying period;
wherein each of the plurality of computing devices comprises a second material applied to a first side of each of the plurality of computing devices, the second material having a second characteristic;
wherein each of the plurality of computing devices comprises a third material applied to a second side of each of the plurality of computing devices, the third material having a third characteristic;
wherein each of the plurality of computing devices is configured to perform, during the drying period, a self-orientation operation.

18. The method of claim 17, wherein each of the plurality of computing devices comprise a second magnetic layer.

19. The method of claim 17, wherein the layer of magnetic material is a patterned layer.

20. The method of claim 17, wherein the layer of the first material is a patterned layer.
